(19) United States
(12) Patent Application Publication
(10) Pub. No.: US 2026/0164568 A1
(43) Pub. Date: Jun. 11, 2026

(54) CONTROL BOX ASSEMBLY AND ELECTRONIC DEVICE COMPRISING SAME

(71) Applicant: SAMSUNG ELECTRONICS CO., LTD., Suwon-si (KR)

(72) Inventors: Gyeongjin KIM, Suwon-si (KR); Changhyun LEE, Suwon-si (KR); Juhyun KIM, Suwon-si (KR)

(73) Assignee: SAMSUNG ELECTRONICS CO., LTD., Suwon-si (KR)

(21) Appl. No.: 19/183,372

(22) Filed: Apr. 18, 2025

Related U.S. Application Data
(63) Continuation of application No. PCT/KR2023/018446, filed on Nov. 16, 2023.

(30) Foreign Application Priority Data
Nov. 17, 2022 (KR) 10-2022-0154639

(51) Int. Cl. H05K 5/00; H05B 6/64

(52) U.S. Cl. CPC H05K 5/0026; H05B 6/6435; H05K 5/0017

(57) ABSTRACT

A control box assembly having a guide member, and a cooking appliance comprising the same. To this end, the control box assembly comprises: a housing; a touch panel arranged on the front surface of the housing so as to enable operation to be performed by a user; a printed circuit board, which is provided inside the housing and includes at least one connection port; a flexible printed circuit board extending from a predetermined point of the touch panel so as to be connected to the connection port; and a guide member provided in the housing. The guide member includes an opening configured to allow the flexible printed circuit board to be introduced into an interior of the housing to connect to the printed circuit board; and at least one rib extending along a height direction of the bottom surface of the housing, which is adjacent to the opening.

### CROSS-REFERENCE TO RELATED APPLICATIONS

This application is a continuation application of International Application No. PCT/KR2023/018446, filed on Nov. 16, 2023, in the Korean Intellectual Property Receiving Office, which claims priority from Korean Patent Application No. 10-2022-0154639, filed on Nov. 17, 2022, in the Korean Intellectual Property Office, the disclosures of which are hereby incorporated by reference herein in their entireties.

### TECHNICAL FIELD

The disclosure relates to a control box assembly having a control button and an electronic device including the same.

### BACKGROUND ART

Electronic devices may be classified according to their functions. Electronic devices may include cooking appliances that may be primarily used in the kitchen for cooking. A microwave oven is one of the cooking appliances that heat the inside and outside of food by irradiating high frequency waves. Microwave ovens have high thermal efficiency, so they may shorten the cooking time of food, or reduce the loss of nutrients during cooking, defrosting, or warming of food.

Microwave ovens are in a trend of being functionally integrated with other kitchen appliances. For example, an over-the-range (OTR) microwave oven is a microwave oven that incorporates the function of a hood that provides ventilation in the kitchen. The OTR microwave oven may be installed on the wall, reducing the installation space and enabling more convenient and efficient food cooling.

Electronic products, including cooking appliances, may contain various types of electronic or electric components inside. For example, in electronic products, electronic or electric components may be integrated on a printed circuit board (PCB). Various types of lines (e.g., FPCB) may be present inside the electronic product to electrically connect a separate assembly, such as a user interface including control buttons or a detergent, to the PCB. Damage (e.g., open circuit) to a line in the electronic product may cause a failure in the normal operation of the electronic product.

### DISCLOSURE OF INVENTION

### Technical Problem

An embodiment of the disclosure may provide a control box assembly and an electronic device having a guide rib to prevent an internal line from contacting a surrounding medium formed of metal, e.g., the case, and an electronic device including the same.

### Technical Solution

A control box assembly according to an embodiment of the disclosure may comprise a housing, a touch panel to be disposed on a front surface of the housing to allow operation to be performed by a user, a printed circuit board, arrangeable inside the housing, and including at least one connection port, a flexible printed circuit board extending from a predetermined point of the touch panel and connected to the at least one connection port, and a guide member arrangeable in the housing. The guide member may include an opening configured to allow the flexible printed circuit board to be introduced into an interior of the housing to connect to the printed circuit board and at least one rib extending in a height direction of a bottom surface of the housing adjacent to the opening.

An electronic device according to an embodiment of the disclosure may include a control box assembly. The control box assembly may comprise a housing including an external case having a synthetic resin material and a bracket panel having a steel material inside the external case, a touch panel to be disposed on a front surface of the housing to easily allow operation to be performed by a user, a printed circuit board, attachable to the bracket panel and including at least one connection port, a flexible printed circuit board including one end electrically coupleable to the touch panel and another end including a second connection port configured to be fitted into and coupled to a first connection port of the printed circuit board, an opening formed to allow passage through the external case and the bracket panel to connect an exterior and an interior of the housing, and a rib configured to have a predetermined height from a bottom surface of the outer case to serve as a barrier between the opening and one side surface of the bracket panel.

The technical objects of the disclosure are not limited to the foregoing, and other technical objects may be derived by one of ordinary skill in the art from example embodiments of the disclosure.

### Advantageous Effects

According to various embodiments of the disclosure, it is possible to block an internal line from contacting a surrounding medium formed of a metallic material by a guide rib. It is possible to mitigate touch defects by the internal line and the surrounding medium formed of a metallic material. It is also possible to prevent a fire that may occur due to contact between a metallic material and an internal line.

Effects of the present invention are not limited to the foregoing, and other unmentioned effects would be apparent to one of ordinary skill in the art from the following description. In other words, unintended effects in practicing embodiments of the disclosure may also be derived by one of ordinary skill in the art from example embodiments of the disclosure.

### BRIEF DESCRIPTION OF DRAWINGS

FIG. 1 is a view illustrating an installation state of a cooking appliance according to an embodiment of the disclosure;

FIG. 2 is an exploded perspective view illustrating a cooking appliance according to an embodiment of the disclosure;

FIG. 3 is a front exploded perspective view illustrating a control box assembly according to an embodiment of the disclosure;

FIG. 4 is a rear exploded perspective view illustrating a portion of a control box assembly according to an embodiment of the disclosure;

FIG. 5 is a perspective view illustrating a control box assembly according to an embodiment of the disclosure;

FIG. 6 is a perspective view illustrating a housing according to an embodiment of the disclosure;

FIG. 7 is a cross-sectional view illustrating a control box assembly according to an embodiment of the disclosure;

FIG. 8 is a perspective view and a plan view illustrating a guide member according to an embodiment of the disclosure;

FIG. 9 is a perspective view and a plan view illustrating a guide member according to an embodiment of the disclosure; and

FIG. 10 is a perspective view and a plan view illustrating a guide member according to an embodiment of the disclosure.

In connection with the description of the drawings, the same or similar reference numerals may be used to denote the same or similar elements.

### MODE FOR THE INVENTION

Hereinafter, embodiments of the disclosure are described in detail with reference to the drawings so that those skilled in the art to which the disclosure pertains may easily practice the disclosure. However, the disclosure may be implemented in other various forms and is not limited to the embodiments set forth herein. The same or similar reference denotations may be used to refer to the same or similar elements throughout the specification and the drawings. Further, for clarity and brevity, no description is made of well-known functions and configurations in the drawings and relevant descriptions.

The terms “x-axis direction”, “y-axis direction”, and “z-axis direction” used in the following description are defined with reference to the drawings for convenience of description, and the shape and position of each component are not limited by these terms.

In the following description, a cooking appliance is specified as an electronic device to which embodiments of the disclosure are applied. However, embodiments of the disclosure are not limited to the cooking appliance, but may be commonly applied to most of electronic devices that use electrical lines to electrically connect the PCB with other electronic or electric assemblies.

Further, in the following description, the cooking appliance 1 is an over-the-range (OTR) microwave oven 1 as an example but, without limitations thereto, may include a regular (free-standing type) microwave oven.

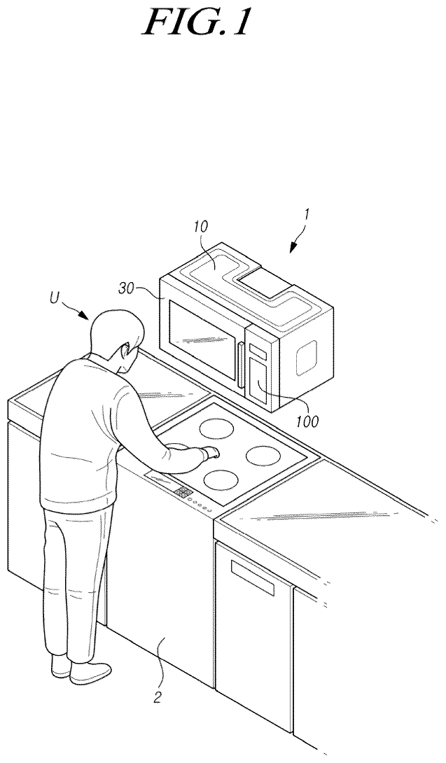

FIG. 1 is a view illustrating an installation state of a cooking appliance 1.

Referring to FIG. 1, the user U may face the cooking appliance 1 in front of the door 30 to use the cooking appliance 1. A right side of the user U may be defined as a +x-axis direction and a left side may be defined as a −x-axis direction. The opposite direction of the user's gaze may be defined as a +y-axis direction, and the gaze direction may be defined as a −y-axis direction. An upper side of the user may be defined as a +z-axis direction and a lower side may be defined as a −z-axis direction. The +x-axis direction may be referred to as a right direction, the −x-axis direction may be referred to as a left direction, the +y-axis direction may be referred to as a front direction, the −y-axis direction may be referred to as a rear direction, the +z-axis direction may be referred to as an upper direction, and the −z-axis direction may be referred to as a lower direction.

For example, when the cooking appliance 1 is an OTR cooking appliance, the cooking appliance 1 may be installed on an upper portion of another cooking appliance 2. Hereinafter, the cooking appliance 1 or the microwave oven may refer to an OTR cooking appliance. The other cooking appliance 2 may be, e.g., a cooktop or an oven installed on the ground. The cooktop may include a gas-type cooktop or an electric cooktop. The oven may include a gas-type oven or an electric oven. Further, the other cooking appliance 2 may correspond to various cooking appliances.

For example, the cooking appliance 1 may include a main body 10, a door 30 provided on the front surface of the main body 10 and having a structure capable of opening and closing, or a control box assembly 100 provided on the front surface of the main body 10 and capable of being controlled by the user U. A display for displaying the state of the cooking appliance 1 may be provided on the front surface of the main body 10.

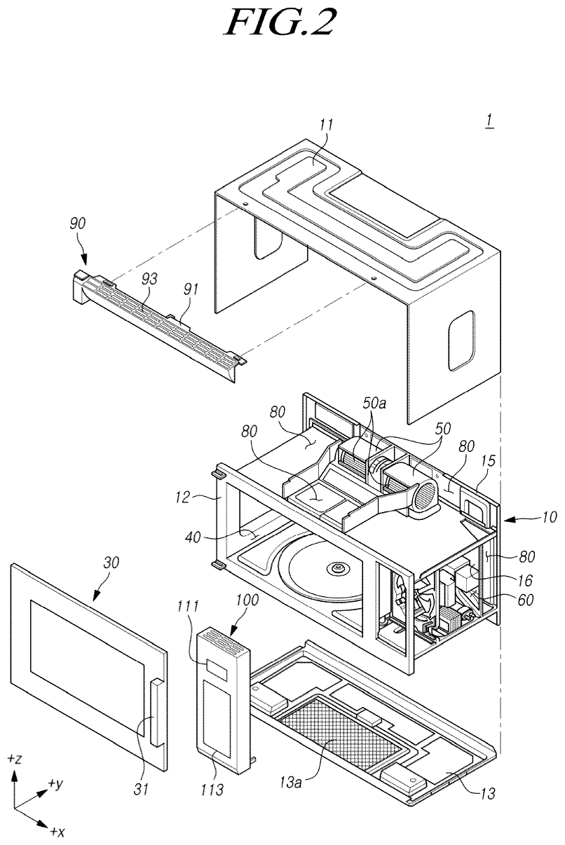

FIG. 2 is an exploded perspective view illustrating a cooking appliance 1 according to an embodiment.

Referring to FIG. 2, the cooking appliance 1 may include a cabinet 11 forming an external appearance of the main body 10. The main body 10 may be positioned on an upper portion of the other cooking appliance 2. A rear surface of the main body 10 may be coupled and fixed to a wall. However, without limitations thereto, the side surface or upper surface of the main body 10 may be coupled and fixed to the wall. Further, according to the user's selection, the cooking appliance 1 may be coupled to the wall and used as a wall-mounted type, or may be used in a state placed on the floor.

The cabinet 11 may include an upper cover forming an upper surface and two opposite side surfaces, and a hood plate 13 as a lower cover forming a lower surface. The hood plate 13 may be provided with an inlet 13a for introducing exhaust gas and water vapor generated from the other cooking appliance 2. The cabinet 11 may include a front frame 12 forming a front surface and a rear plate 15 forming a rear surface. The upper cover, the front frame 12, the hood plate 13, or the rear plate 15 may be separately provided. All or some of the upper cover, the front frame 12, the hood plate 13, or the rear plate 15 may be integrated.

The inside of the main body 10 may be divided into a cooking chamber 40 or an electronic equipment chamber 60. The front surface of the cooking chamber 40 may be open so that food may be put therein. The electronic equipment chamber 60 may be formed outside the cooking chamber 40. Various electronic components may be installed in the electronic equipment chamber 60. Specifically, the outer appearance of the main body 10 may be formed by the upper cover, the hood plate 13, the front frame 14, or the rear plate 15. For example, the electronic equipment chamber 60 may correspond to the whole or part of the space between the cooking chamber 20 and the cabinet 11.

A door 30 having a hinged side may be installed on the front surface of the cabinet 11 to open and close the cooking chamber 40. The cooking chamber 40 may be provided with a tray (not shown) on which the food to be cooked may be seated. The tray may be rotated by having a motor installed thereunder.

The door 30 is coupled to the main body 10 and may be provided to open and close the cooking chamber 40. The door 30 may be rotatably coupled to the main body 10. The door 30 may be provided to be rotatable with respect to the main body 10 by being connected to the hinges coupled to two opposite edges of the front frame 12 of the main body 10. However, in addition to the rotation method, the door 30 may be provided to move up and down, left and right, or forward and rearward.

The door 30 may include a door handle 31. The door handle 31 may be provided on one side of the door 30 to open and close the cooking chamber 40.

A control box assembly 100 capable of selecting the intensity or operation time of the microwave according to the amount of food may be coupled to the cabinet 11. The control box assembly 100 may be provided next to the cooking chamber 40. The control box assembly 100 may be disposed at the rear of the door 30 so as to be covered by the door 30 in the closed state of the door 30, but is not limited thereto. The control box assembly 100 may be disposed next to the door 30 so as to be exposed to the outside even in the closed state of the door 30.

The control box assembly 100 may receive a signal for the operation of the cooking appliance 1 and output information about the operation of the cooking appliance 1. More specifically, the control box assembly 100 may receive a signal for cooking the food and output information about the cooking of the food.

The control box assembly 100 may include a display area 111 and a touch area 113. The display area 111 may display information according to a signal input through the touch area 113 by the user (e.g., the user U of FIG. 1). The display area 111 may output a cooking signal or cooking information about food. The touch area 113 may include a function button (not shown). The function button may include, e.g., a button related to a cooking mode, a cooking time, and a cooking temperature. An electrical signal may be generated in the touch area 113 through a touch or press of the user U. The electrical signal may be transferred to a controller (not shown) provided in the electronic equipment chamber 60. The controller may perform control for displaying information corresponding to the electrical signal on the display area 111.

A detailed description of the control box assembly 100 is given below.

A hood flow path 80 through which air including exhaust gas sucked through the inlet 13a flows may be formed inside the cabinet 11. As shown in FIG. 2, the cooking appliance 1 may be provided with a partition plate 16 that partitions the hood flow path 80 and the electronic equipment chamber 60 to prevent the air flowing through the hood flow path 80 from passing over to the electronic equipment chamber 60. However, without limitations thereto, the partition plate 16 may be omitted. In this case, there is no distinction between the electronic equipment chamber 60 and the hood flow path 80, and the whole or part of the space between the cooking chamber 40 and the cabinet 11 may correspond to the hood flow path 80.

The hood flow path 80 may have one end communicating with the inlet 13a and the other end communicating with the discharge portion 90. Accordingly, if the air containing exhaust gas outside the cooking appliance 1 is introduced through the inlet 13a, the introduced air may flow along the hood flow path 80 inside the main body 10 and be discharged back to the outside of the cooking appliance 1 through the discharge portion 90.

The discharge portion 90 may include a grill frame 91. The grill frame 91 may be provided on the upper surface of the discharge portion 90, for example. The grill frame 91 may be provided in a lattice shape extending in the x-axis direction and the y-axis direction. A plurality of discharge ports 93 partitioned by the grill frame 91 provided in the discharge portion 90 may be formed.

Air flowing into and out of the main body 10 may flow through the discharge portion 90. For example, air containing pollutants generated during the process of cooking food in the other cooking appliance (e.g., the other cooking appliance 2 of FIG. 1) installed under the main body 10 and sucked into the main body 10 may be discharged to the outside of the cooking appliance 1 through the discharge portion 90. For example, air containing pollutants generated in the process of cooking food (not shown) in the cooking chamber 40 may also be discharged to the outside through the discharge portion 90.

The cooking appliance 1 may include a blower 50 provided to form an airflow inside the hood flow path 80 for a hood function. The blower 50 may be installed inside the cabinet 11. Specifically, the blower 50 may be disposed at the rear upper end inside the cabinet 11 and may be disposed on the hood flow path 80.

The blower 50 may include a cross flow fan or a sirocco fan. However, without limitations thereto, other types of fans may be included. The blower 50 may have two air outlets 50a, and air may be discharged from the air outlets 50a.

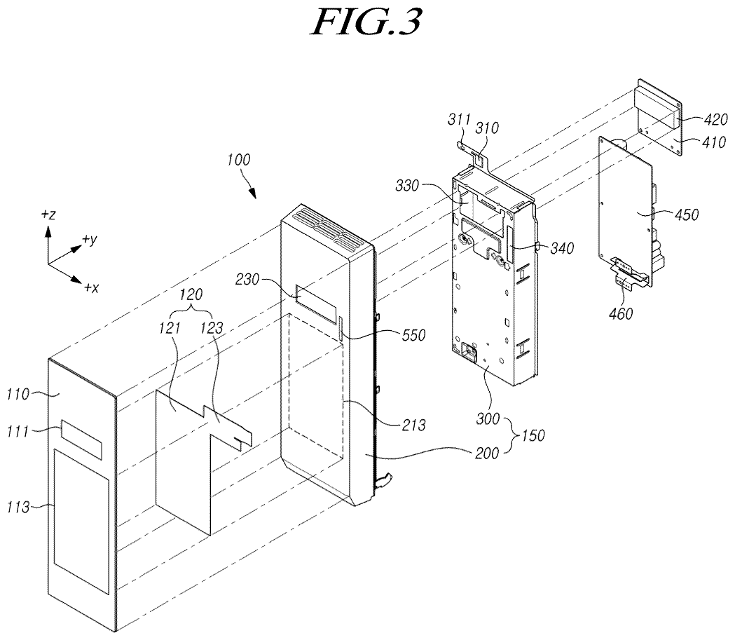

FIG. 3 is a front exploded perspective view illustrating a control box assembly 100 according to an embodiment. In other words, FIG. 3 is an exploded perspective view of the control box assembly 100 as viewed from the front to the rear (+y-axis direction).

Referring to FIG. 3, the control box assembly 100 may include a glass member 110, a touch panel 120, a housing 150, a first printed circuit board (PCB) 410, or a second printed circuit board 450. Hereinafter, the first printed circuit board 410 is referred to as a first PCB 410, and the second printed circuit board 450 is referred to as a second PCB 450.

The control box assembly 100 may be configured by sequentially combining the glass member 110, the touch panel 120, the outer case 200, the bracket panel 300, the first PCB 410, and the second PCB 450.

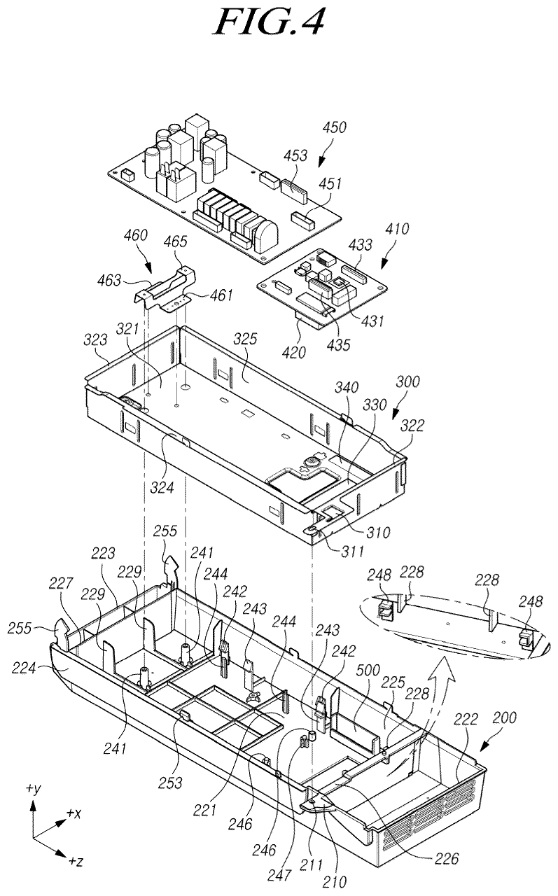

The glass member 110 may be attached to the front surface of the outer case 200. The area of the glass member 110 may be substantially the same as the area of the first frame (e.g., the first frame 221 of FIG. 4) of the outer case 200.

The glass member 110 may include a display area 111 and a touch area 113. The display area 111 may be an area in which information output from the display 420 is displayed. Each display area 111 may be an area corresponding as a display window 230 of the external case 200, a display window 330 of the bracket panel 300, and a display 420 are coupled.

The touch area 113 may correspond to an area corresponding to the first area 121 when the touch panel 120 is attached to the front surface of the outer case 200. Although not shown, the touch area 113 may include, e.g., a plurality of cells divided into predetermined areas. In the plurality of cells, e.g., information about the cooking mode, the cooking time, and the cooking power may be printed. The user U may control the cooking appliance 1 by touching or pressing the plurality of cells.

The touch panel 120 may include a first area 121 and a second area 123. The first area 121 of the touch panel 120 may generate an electrical signal through a touch or press of the user U. The first area 121 may have a substantially rectangular shape, for example. However, the touch panel 120 is not limited to the shape, and may have various shapes as necessary. The outer case 200 may include a touch panel seating portion 213 for attaching the first area 121 of the touch panel 120 to the outer case 200. The touch panel seating portion 213 may have, e.g., a shape corresponding to the shape of the first area 121. Although not shown, the touch panel seating portion 213 may be recessed so that the touch panel 120 may be attached thereto. The touch panel seating portion 213 may be formed as a partial area thereof is stepped from the remaining area to attach the touch panel 120.

The second area 123 may extend from a predetermined point of the first area 121. The second area 123 may be, e.g., a connector for transferring an electrical signal generated from the touch panel 120 to the first PCB 410 provided in the control box assembly 100. The second area 123 may be implemented as a flexible printed circuit board (FPCB). The second area 123 may pass through the opening 550 provided in the outer case 200 to connect to the connection port of the first PCB 410 provided inside the bracket panel 300. A connection terminal may be provided at one end of the second area 123. The touch panel 120 may be electrically and physically connected to the first PCB 410 through the connection terminal. The second area 123 may have a narrow and long rectangular shape, for example. However, without limitations thereto, the second area 123 may have various shapes as necessary. Hereinafter, the second area 123 is referred to as an FPCB 123.

The housing 150 may constitute the outer appearance of the control box assembly 100. The housing 150 may include an outer case 200 and a bracket panel 300. The housing 150 may be formed, e.g., by coupling the outer case 200 and the bracket panel 300.

The outer case 200 may be formed by molding a synthetic resin material including plastic. The outer case 200 may be formed by injection-molding a synthetic resin material. The outer case 200 may have, e.g., a shape of a polyhedron having an open rear surface. The outer case 200 may have a hexahedral shape having a substantially open rear surface. A glass seating portion for attaching the glass member 110 to the front surface of the outer case 200 may be provided. For example, the glass seating portion may be formed as a portion of the front surface of the outer case 200 is depressed to correspond to the shape of the glass member 110. For example, the glass seating portion may be formed, e.g., as a front partial area of the external case 200 is stepped from the remaining area corresponding to the shape of the glass member 110.

The display window 230 may be formed in the outer case 200. The display window 230 may be formed by, e.g., cutting a portion of the glass seating portion. The display window 230 may be cut to correspond to, e.g., the cross-sectional area of the display 420. The display window 230 may provide a space in which the display 420 connected to the first PCB 410 is to be provided.

The bracket panel 300 may be coupled to the rear surface of the outer case 200. The outer case 200 may include one or more fixing bosses, guide bosses, or guide ribs for coupling the bracket panel 300. The outer case 200 may include one or more guide ribs for supporting the first PCB 410 or the second PCB 450.

The bracket panel 300 may be coupled to the inside of the outer case 200. The bracket panel 300 may provide a space in which the first PCB 410, the second PCB 450, or electronic components are to be provided. The bracket panel 300 may be formed of, e.g., a metallic material. For example, when a fire occurs inside the control box assembly 100, the bracket panel 300 formed of the metallic material may prevent the fire from spreading to the outer case 200.

The bracket panel 300 may include a ground portion 310. The ground portion 310 may be formed to extend from a predetermined area of the bracket panel 300. The ground portion 310 may ground an electrical signal generated from the first PCB 410 or the second PCB 450. A hole 311 may be provided in one end of the ground portion 310. A protrusion (e.g., the protrusion 210 of FIG. 4) provided in the outer case 200 may be bolted to the ground portion 310 through the hole 311. The coupling relationship between the components of the control box assembly 100 is described below in FIG. 4.

The display window 330 may be provided on the bracket panel 300. The display window 330 may be formed by cutting a portion of the bracket panel 300, for example. The display window 330 may be cut to correspond to, e.g., the cross-sectional area of the display 420. The display window 330 may provide a space in which the display 420 is to be provided.

The rib window 340 may be provided on the bracket panel 300. The rib window 340 may be formed by, e.g., cutting a portion of the bracket panel 300. The rib window 340 may provide a space in which the rib (e.g., the guide member 500 of FIG. 4) provided in the outer case 200 is to be provided. The rib window 330 may be cut to correspond to the cross-sectional area of the guide member 500, for example.

The first PCB 410 may be disposed inside the bracket panel 300. The first PCB 410 may be electrically or physically coupled to the display 420. The display 420 may display cooking information. The display 420 may display various information including, e.g., the cooking time, the cooking mode, and the cooking power. The display 420 may output the information according to a control signal transferred from a controller provided on the first PCB 410.

The first PCB 410 may control an electrical signal generated by control of the control box assembly 100 through the touch panel 120 or an electrical signal to be output to the display 420.

The second PCB 450 may be disposed inside the bracket panel 300. The second PCB 450 may be electrically and physically connected to the first PCB 410. For example, the second PCB 450 may be connected to the first PCB 410 through a connector. Two opposite ends of the connector may be connected to connection ports provided in the first PCB 410 and the second PCB 450, respectively.

The connection bracket 460 may be coupled to the front surface of the second PCB 450 to fix the second PCB 450 to the bracket panel 300. Due to the connection bracket 460, the second PCB 450 may be disposed to be spaced apart from the bottom surface of the bracket panel 300 as compared with the first PCB 410.

FIG. 4 is a rear exploded perspective view illustrating a portion of a control box assembly 100 according to an embodiment. To avoid duplicate description, some components (e.g., the glass member 110 or the touch panel 120) are omitted. Hereinafter, the x-axis direction may be referred to as a width direction, the y-axis direction may be referred to as a height direction, and the z-axis direction may be referred to as a length direction.

Referring to FIG. 4, the outer case 200 may have a shape of a polyhedron having one open surface. The outer case 200 may include, e.g., a first frame 221 constituting a front surface and second to fifth frames 222, 223, 224, and 225 constituting the outer wall. The outer case 200 may include, e.g., a second frame 222 constituting an upper surface, a third frame 223 constituting a lower surface, a fourth frame 224 constituting a left surface, and a fifth frame 225 constituting a right surface. The outer appearance of the control box assembly 100 may be configured by the first to fifth frames 221, 222, 223, 224, and 225. The outer case 200 may be provided with an inner space in which the bracket panel 300 is to be disposed by the first to fifth frames 221, 222, 223, 224, and 225.

For example, the touch panel 120 or the glass member 110 may be attached to the front surface of the first frame 221. The front surface of the first frame 221 may be formed so that a partial area thereof is recessed or stepped to attach the touch panel 120 or the glass member 110.

A plurality of vent holes may be formed in the second frame 222. The ventilation hole may be a passage through which air for cooling electrical components disposed inside the electronic equipment chamber (e.g., the electronic equipment chamber 60 of FIG. 2) is sucked. The electrical components may be cooled by air flowing into the electronic equipment chamber 60 through the ventilation holes formed in the second frame 222.

The first partition plate 226 or the second partition plate 227 may be provided at points spaced apart from the second frame 222 and the third frame 223, respectively, by a predetermined distance in the z-axis direction. The first partition plate 226 and the second partition plate 227 may form a space in which the bracket panel 300 is to be provided, for example. The first partition plate 226 and the second partition plate 227 may have a predetermined height. For example, the predetermined height may be substantially the same as the heights of the second to fifth frames 222, 223, 224, and 225.

The first partition plate 226 may include at least one spacing plate 228. The at least one spacing plate 228 may have substantially the same height as the first partition plate 226. The at least one spacing plate 228 may extend in the-z-axis direction from any point of the first partition plate 226. When the at least one spacing plate 228 includes a plurality of spacing plates 228, each spacing plate may have substantially the same length.

The second partition plate 227 may include at least one spacing plate 229. The at least one spacing plate 229 may have substantially the same height as the second partition plate 227. The at least one spacing plate 229 may extend in the +z-axis direction from any point of the second partition plate 227. When the at least one spacing plate 229 includes a plurality of spacing plates 228, each spacing plate may have substantially the same length.

At least one spacing plate 228 provided on the first partition plate 226 and at least one spacing plate 229 provided on the second partition plate 227 may space the bracket panel 300 apart from the outer case 200 by a predetermined distance when the bracket panel 300 is coupled to the outer case 200. Alternatively, when the bracket panel 300 is coupled to the outer case 200, the spacing plate 228, 229 may be fittingly coupled to the opening formed at the point corresponding to the spacing plate 228, 229 in the bracket panel 300. The spacing plates 228 and 229 may support the bracket panel 300 coupled to the outer case 200. For example, the spacing plates 228 and 229 may prevent the bracket panel 300 from shaking or escaping off the outer case 200 when impact or vibration occurs in the control box assembly 100.

A plurality of first fixing bosses 241 may be provided in the first frame 221. The first fixing boss 241 may be formed to protrude in the height direction from the bottom surface of the first frame 221. The first fixing boss 241 may have a predetermined height. The first fixing boss 241 may fix the bracket panel 300 to the outer case 200. The first fixing boss 241 may fix the second PCB 450 disposed on the bracket panel 300. The first fixing boss 241 may space the second PCB 450 apart by a predetermined height. Accordingly, the first fixing boss 241 may secure a space in which the first PCB 410 and the second PCB 450 are to be disposed inside the limited space of the bracket panel 300. An opening may be formed in the bracket panel 300 at a point corresponding to the first fixing boss 241 so that the first fixing boss 241 may pass therethrough. An opening where a bolt or a male screw may be coupled may be provided in the axial direction (height direction) of the first fixing boss 241. The outer case 200, the bracket panel 300, and the second PCB 450 may be coupled in the height direction through the opening. A portion of the first fixing boss 241 may correspond to an opening provided on an upper side of the connection bracket 460.

A plurality of bracket fixing clips 242 may be provided in the fourth frame 224 or the fifth frame 225. The bracket fixing clip 242 may protrude from any point of the fourth frame 224 or the fifth frame 225 in the width direction. The bracket fixing clip 242 may fit and fix the bracket panel 300 into the outer case 200. An upper side of the bracket fixing clip 242 may be provided as an inclined surface. The bracket fixing clip 242 may be implemented in a stop jaw shape. When the bracket panel 300 is seated on the outer case 200, openings provided in two opposite sides 324 and 325 of the bracket panel 300 may be coupled with the bracket fixing clips 242 provided in the outer case 200. The bracket fixing clip 242 and the opening provided in the bracket panel 300 may correspond to each other. The bracket fixing clip 242 may be fitted and coupled through the opening provided in the bracket panel 300, for example. Due to the fitting coupling, the fixing of the outer case 200 and the bracket panel 300 may be strengthened. Further, the fitting coupling may prevent the bracket panel 300 from escaping off the outer case 200 due to an impact or vibration applied to the control box assembly 100.

A plurality of first guide bosses 243 may be provided in the first frame 221. The first guide boss 243 may guide the second PCB 450 to be disposed on the bracket panel 300. At least some of the first guide bosses 243 may have one end formed into a ‘C’ shape to correspond to the edge of the second PCB 450, for example. One end of the first guide boss 243 may contact any one of the edge of the second PCB 450. The first guide boss 243 may pass through the bracket panel 300. An opening may be provided in an area of the bracket panel 300 corresponding to the first guide boss 243.

A plurality of second fixing bosses 244 may be provided in the first frame 221. The second fixing boss 244 may be formed to extend in the height direction from any point on the first frame 221. The second fixing boss 244 may guide the second PCB 410 to be spaced apart on the bracket panel 300 by a predetermined height. One end of the second fixing boss 244 may pass through the through hole provided in the substrate of the first PCB 410.

At least one substrate fixing boss 246 or substrate fixing protrusion 247 may be provided in the first frame 221. When the first PCB 410 is fixed to the bracket panel 300, the substrate fixing boss 246 may be screwed and fixed through the opening of the first PCB 410. A through hole may be provided in the substrate fixing boss 246 to be coupled with a screw or a bolt. The substrate fixing protrusion 247 may be fittingly coupled into the opening provided in the first PCB 410. The substrate fixing boss 246 or the substrate fixing protrusion 247 may pass through the bracket panel 300. An opening may be provided in the bracket panel 300 to allow the substrate fixing boss 246 or the substrate fixing protrusion 247 to pass therethrough.

One or more second guide bosses 248 may be provided in the first frame 221. The second guide boss 248 may be formed to extend in the height direction from any point on the first frame 221 and then in the-z direction. At least some of the second guide bosses 248 may have one end formed into a ‘C’ shape to correspond to the edge of the first PCB 410, for example. The second guide boss 248 may guide the first PCB 410 to be disposed on the bracket panel 300. One end of the second guide boss 248 may contact any one of the edge of the first PCB 410.

At least one stop jaw 251, 253, and 255 may be provided on the upper surface of the fourth frame 224 or the fifth frame 225. The at least one stop jaw 251, 253, and 255 may include a first stop jaw 251, a second stop jaw 253, or a third stop jaw 255. The control box assembly 100 may be coupled to the main body 10 through the at least one stop jaw 251, 253, and 255. When the control box assembly 100 is coupled to the main body 10, an opening may be provided in the main body 10 in an area corresponding to the stop jaw 251, 253, and 255.

Each of the first stop jaw 251, the second stop jaw 253, or the third stop jaw 255 may be positioned on the same line as the fourth frame 224 or the fifth frame 225. At least some of the at least one stop jaw 251, 253, and 255 may be formed in, e.g., an ‘L’shape.

The guide member 500 may be provided in the first frame 221. The guide member 500 may be integrally formed with the outer case 200. The guide member 500 may be formed of a synthetic resin material including plastic. The guide member 500 may extend in the height direction from any position of the first frame 221. The guide member 500 may pass through the rib window 340 provided on the bracket panel 300. The guide member 500 may be spaced apart from the fifth frame 225 by a predetermined distance in the width direction. The guide member 500 may have a predetermined height. Hereinafter, the guide member 500 is described below in detail.

The guide member 500 may include an opening 550. The FPCB 123 provided on the touch panel 120 may pass through the rear surface from the front surface of the outer case 200 through the opening 550 and may be drawn into the inside.

The bracket panel 300 may be formed of metal. The bracket panel 300 may include a first frame 321 constituting a front surface or second to fifth frames 322, 323, 324, and 325 constituting the outer wall. For example, the bracket panel 300 may include a second frame 322 constituting an upper surface, a third frame 323 constituting a lower surface, a fourth frame 324 constituting a left surface, or a fifth frame 325 constituting a right surface. One side of the second to fifth frames 322, 323, 324, and 325 may be bent in the direction of the second to fifth frames 222, 223, 224, and 225 of the adjacent outer case 200.

The bracket panel 300 may include a ground portion 310. The ground portion 310 may extend outward from the first frame 321. The ground portion 310 may contact the rear surface of the outer case 200 so that the control box assembly 100 is grounded. A hole 311 may be provided in one end of the ground portion 310. The hole 311 may correspond to the hole 211 provided in the protrusion 210 of the outer case 200. The fastening member (e.g., screw or bolt) may penetrate the hole 311 provided in the ground portion 310 and the hole 211 provided in the outer case 200.

The connection bracket 460 may be connected to the rear surface of the first frame 321 of the bracket panel 300. The connection bracket 460 may connect the bracket panel 300 and the second PCB 450. The connection bracket 460 may include a first member 461 and a second member 463 in contact with the bracket panel 300 or a third member 465 in contact with the second PCB 450. A through hole for coupling a screw or a bolt to connect to the bracket panel 300 may be formed in the first member 461 and the second member 463. The third member 465 may be formed to extend from the first member 461 and the second member 463 in the height direction. Through holes for coupling a screw or a bolt to connect to the second PCB 450 may be formed in two opposite ends of the third member 465.

At least one electronic component or connection port may be provided on the first PCB 410. The electronic components may include a first electronic component 431. The first electronic component 431 may be implemented as, e.g., an integrated chip (IC). The first electronic component 431 may input/output a signal for controlling the display 420 or the touch panel 120, for example.

The first PCB 410 may include at least one connection port 433 and 435. The at least one or more connection ports 433 and 435 may include a first connection port 433 or a second connection port 435. The FPCB 123 of the touch panel 120 may pass through the guide member 500 to connect to the first connection port 433. Thus, the touch panel 120 and the first PCB 410 may be electrically and physically connected to each other. For example, one end of a wire to connect the first PCB 410 and the second PCB 450 may be electrically and physically connected to the second connection port 435.

The display 420 may be attached to the front surface of the first PCB 410. The display 420 may be electrically and physically connected to the first PCB 410. The display 420 may receive a control signal output from the first electronic component 431. The display 420 may be exposed to the front surface of the control box assembly 100 through the display window 330 provided on the bracket panel 300 and the display window 230 provided on the outer case 200. The display 420 may output various pieces of information about the cooking time, the cooking mode, or the cooking power.

At least one electronic component or connection port 461 and 463 may be provided on the second PCB 450. The at least one or more electronic components may receive an electrical signal generated by the user U touching or pressing a button through the touch panel 120, for example. The second PCB 450 may transfer the electrical signal to the first PCB 410. The other end of the wire connected to the second connection port 435 provided in the first PCB 410 may be connected to the connection ports 461 and 463 provided on the second PCB 450. At least one other end of the wire may be configured. The connection terminal provided at the other end may be electrically and physically connected to at least one of the connection ports 461 and 463 provided on the second PCB 450.

The first PCB 410 and the second PCB 450 may be provided at different heights of the bracket panel 300. The first PCB 410 may be provided, e.g., at a position adjacent to the first frame 321 of the bracket panel 300. The second PCB 450 may be, e.g., provided to be more spaced apart from the first frame 321 in the height direction than the first PCB 410.

In addition to those illustrated, the first PCB 410 or the second PCB 450 may be provided with various electronic components or connection components.

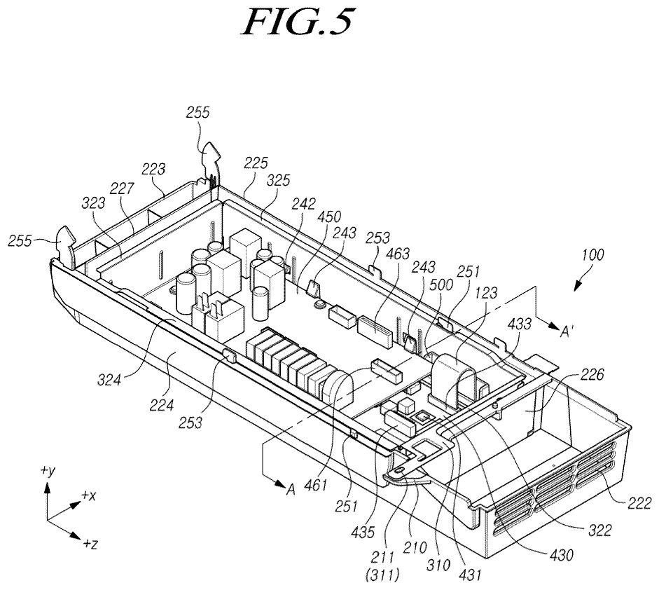

FIG. 5 is a rear perspective view illustrating a control box assembly 100 according to an embodiment.

Referring to FIG. 5, the bracket panel 300 may be seated in a space formed by the first frame 221, the fourth frame 224, the fifth frame 225, the first partition plate 226, or the second partition plate 227 of the outer case 200. The first PCB 410 or the second PCB 450 may be disposed in the space formed by the first to fifth frames 321, 322, 323, 324, and 325 of the bracket panel 300. The first PCB 410 may be disposed closer to the first frame 321 of the bracket panel 300 than the second PCB 450. The second PCB 450 may be disposed to be spaced apart from the first PCB 410 in the height direction.

The first PCB 410 and the second PCB 450 may be electrically and physically connected to each other. Some or all of the second connection ports 435 and 463 provided on the first PCB 410 and at least one connection port 461 and 463 provided on the second PCB 450 may be connected by a wire (not shown).

The FPCB 123 of the touch panel 120 attached to the front surface of the outer case 200 may pass through the opening 550 provided in the guide member 500 to connect to the first PCB 410. The connection terminal provided at the end of the FPCB 123 may be connected to the first connection port 433 provided on the first PCB 410.

The guide member 500 may prevent the FPCB 123 of the touch panel 120 from contacting the bracket panel 300. The flexible FPCB 123 may be moved by ambient vibration or impact. Therefore, the guide member 500 may prevent the FPCB 123 from contacting one area of the bracket panel 300, especially the fifth frame 325. If the FPCB 123 contacts the bracket panel 300, all or portion of the electrical signals generated by the user U touching or pressing the touch area 113 provided in the control box assembly 100 may be transferred to the metallic bracket panel 300 while being transferred through the FPCB 123. The electrical signal transferred to the bracket panel 300 may be grounded through the ground portion 310. Therefore, an error may occur as the input signal is not completely transferred to the first electronic component 431 provided on the first PCB 410.

Instead of providing the guide member 500 having a covering wall structure in the outer case 200, widening only the width or length of the opening 550 may be vulnerable to fire occurring in the control box assembly 100. By widening the width of the opening 550, a fire generated in the bracket panel 300 may easily spread to the outer case 200. Further, widening only the width or length of the opening 550 may not substantially prevent the FPCB 123 of the touch panel 120 from contacting the bracket panel 300.

The guide member 500 may be integrally formed with the outer case 200. The manufacturing process of the guide member 500 integrally molded with the outer case 200 may be simplified as compared to a structure that prevents contact by covering the surroundings of the FPCB 123 of the touch panel 120 with a member (not shown, hereinafter referred to as a cover member) in a case form. Further, the guide member 500 may produce the control panel assembly 100 at a lower cost than the cover member.

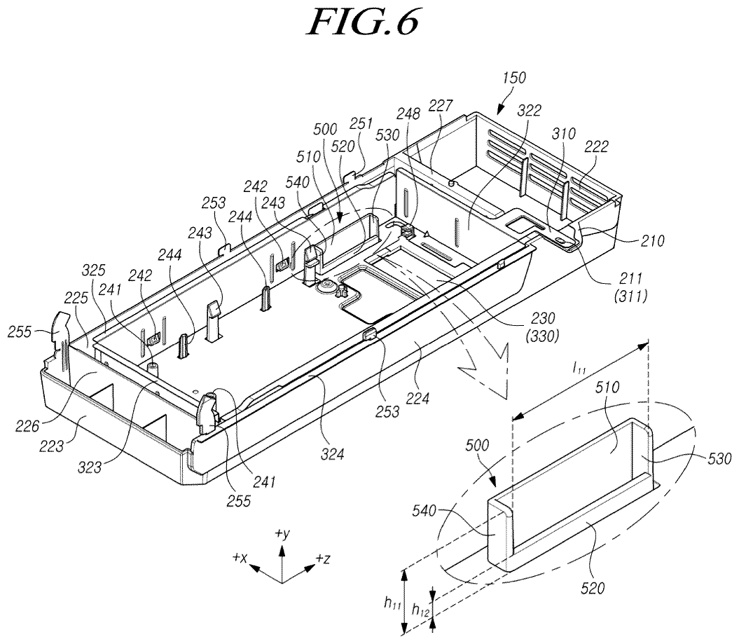

FIG. 6 is a perspective view illustrating a housing 150 according to an embodiment.

Referring to FIG. 6, the bracket panel 300 may be coupled in the rear direction (e.g., the-y-axis direction) of the outer case 200. When combined, structures provided in the outer case 200 (e.g., the first fixing boss 241, the fixing clip 242, the first guide boss 243, the second fixing boss 244, and the second guide boss 248) may pass through the openings provided in the bracket panel 300.

The guide member 500 may be formed by extending from the outer case 200 in the height direction. The guide member 500 may pass through the rib window 340 provided on the bracket panel 300. The guide member 500 may include at least one wall having a predetermined height. The at least one wall may be implemented, e.g., in the form of a barrier.

The guide member 500 may include an opening 550. The opening 550 may be formed by cutting a portion of the outer case 200. The opening 550 may be provided to allow the FPCB 123 of the touch panel 120 attached to the front surface to pass therethrough. For example, the height of the opening 550 may be substantially the same as the thickness of the first frame 221 constituting the outer case 200 in the height direction. The opening 550 may have a substantially rectangular shape, but is not limited thereto, and may have various shapes corresponding to the shape of the FPCB 123 of the touch panel 120.

The at least one wall may extend in the height direction (e.g., the +y-axis direction) from the edge of the opening 550. The at least one wall may include, e.g., a first rib 510, a second rib 520, a third rib 530, or a fourth rib 540. All or some of the first to fourth ribs 510, 520, 530, and 540 may integrally form the guide member 500.

The first rib 510 may be positioned at a distance closest to the sidewall (e.g., the fifth frame 325) of the bracket panel 300, for example. The first rib 510 may substantially prevent one surface of the FPCB 123 of the touch panel 120 adjacent to the fifth frame 325 from contacting the bracket panel 300. The first rib 510 may have a height of, e.g., h₁₁.

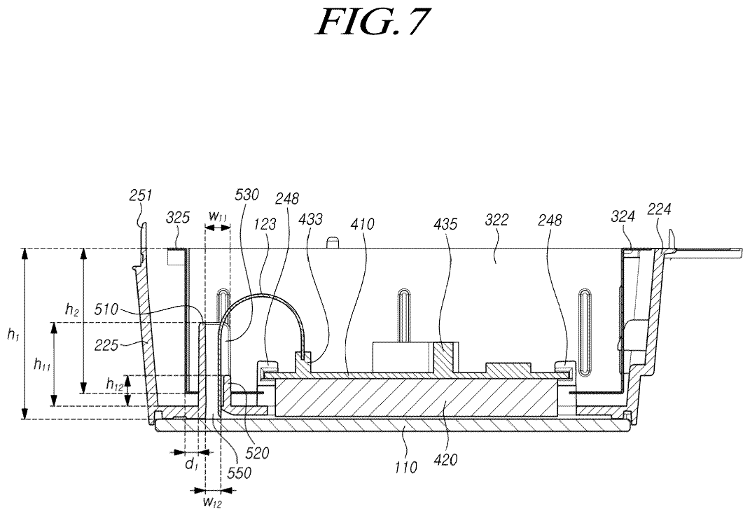

The second rib 520 may be positioned, e.g., to be spaced apart from the first rib 510 by a predetermined distance in the-x-axis direction. The second rib 520 may substantially prevent the other surface of the FPCB 123 of the touch panel 120 from contacting the bracket panel 300. The second rib 520 may have a height of, e.g., h₁₂. The width (e.g., the width w₁₁ of the guide member 500 of FIG. 7) may be determined by the first rib 510 and the second rib 520.

The first rib 510 or the second rib 520 may have a length of l₁₁. The length l₁₁ of the first rib 510 or the second rib 520 may be at least equal to or larger than the length of the FPCB 123 of the touch panel 120.

The third rib 530 or the fourth rib 540 may constitute, e.g., a sidewall of the guide member 500. Due to the third rib 530 or the fourth rib 540, the length of the guide member 500 may be determined. The third rib 530 or the fourth rib 540 may prevent, e.g., the FPCB 123 of the touch panel 120 from moving in the length direction. For example, the third rib 530 or the fourth rib 540 may prevent the FPCB 123 from coming into contact with an electronic component provided on the bracket panel 300. The third rib 530 or the fourth rib 540 may have a height of, e.g., h₁₁.

Some of the second to fourth ribs 520, 530, and 540 may be omitted from the guide member 500. For example, the guide member 500 may be formed of the first rib 510. Alternatively, the guide member 500 may include the first rib 510 or the second rib 520. Alternatively, the guide member 500 may include the first rib 510, the third rib 530, or the fourth rib 540.

The guide member 500 may be formed to be spaced apart from the bracket panel 300 by a predetermined distance in the-x-axis direction. Hereinafter, the distance from the fifth frame 225 of the bracket panel 300 to the first rib 510 is referred to as a separation distance (e.g., the separation distance d₁ of FIG. 7). The separation distance may have a complementary relationship with the height of the guide member 500. For example, as the separation distance d₁ increases, the maximum height of the guide member 500 may decrease. Alternatively, as the separation distance d₁ decreases, the maximum height of the guide member 500 may increase.

The position of the guide member 500 may be determined considering the positions of components to be disposed on the bracket panel 300. For example, the position may be determined considering the arrangement relationship with the first guide boss 243, the first PCB 410, the second PCB 450, the display 420, or the second guide boss 248 adjacent to the guide member 500. The guide member 500 may be provided at a position capable of minimizing interference with the components, for example. Without limitations thereto, the position of the guide member 500 may be determined considering the positions of components inside the control box assembly 100.

FIG. 7 is a cross-sectional view illustrating a control box assembly 100 according to an embodiment. In other words, FIG. 7 is a cross-sectional view taken along plane x-y on point A-A′ of the control box assembly 100 of FIG. 5 and viewed in the +z-axis direction.

Referring to FIG. 7, the second to fifth frames 222, 223, 224, and 225 of the outer case 200 may have a predetermined height. The predetermined height may be, e.g., h₁.

The second to fifth frames 322, 323, 324, and 325 of the bracket panel 300 may have a predetermined height. The predetermined height may be, e.g., h₂. h₂ may be at least equal to or less than h₁.

The height of the first rib 510 of the guide member 500 may be, e.g., h₁₁. The height of the third rib 530 or the fourth rib 540 of the guide member 500 may be, e.g., h₁₁. When the FPCB 123 of the touch panel 120 is connected to the connection port 433 provided on the first PCB 410, it may be bent in the +x-axis direction. The height of the first rib 510 may be determined considering the maximum height of the bent FPCB 123 in the y-axis direction.

The guide member 500 may be spaced apart from the fifth frame 325 of the bracket panel 300 by d₁. The distance between the first rib 510 and the fifth frame 325 of the guide member 500 may be referred to as a separation distance d₁.

The height h₁₁ of the first rib 510 and the separation distance d₁ may have a complementary relationship. If the position of the first rib 510 is determined so that the separation distance d₁ increases, the height h₁₁ of the first rib 510 may be formed to decrease. If the position of the first rib 510 is determined so that the separation distance d₁ decreases, the height h₁₁ of the first rib 510 may be formed to increase.

The height of the second rib 520 of the guide member 500 may be, e.g., h₁₂. When the FPCB 123 of the touch panel 120 is connected to the connection port 433 provided on the first PCB 410, the height h₁₂ of the second rib 520 may be determined considering the maximum height of the bent FPCB 123 in the y-axis direction.

The opening 550 of the guide member 500 may have a width of w₁₂. The width w₁₂ of the opening 550 may be determined considering the flexibility of the FPCB 123 of the bent touch panel 120. The width w₁₂ of the opening may be determined considering the width of the rib window 340 provided on the bracket panel 300. Alternatively, the width w₁₂ of the opening 550 may be determined considering the width of the rib window 340 provided on the bracket panel 300.

The shape of the guide member 500 is not limited to that illustrated, but may be variously implemented to prevent contact with the FPCB 123 of the touch panel 120.

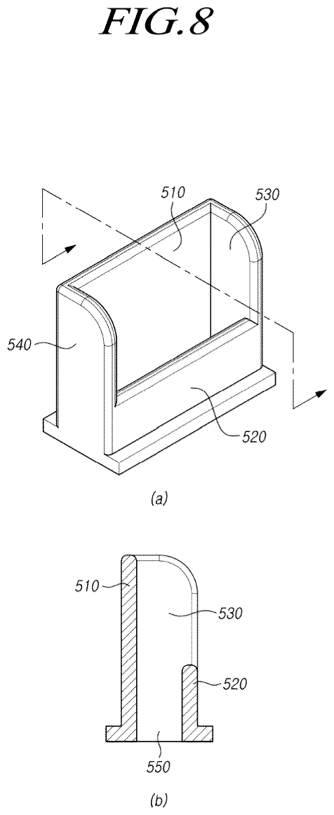

FIG. 8 is a perspective view (a) and a cross-sectional view (b) of a guide member 500 according to an embodiment.

According to FIG. 8, the guide member 500 may include a first rib 510, a second rib 520, a third rib 530, a fourth rib 540, and an opening 550. The first to fourth ribs 510, 520, 530, and 540 may be formed to extend in the height direction from the outer case 200 adjacent to the opening 550. The guide member 500 may be integrally formed with the outer case 200. The guide member 500 may be formed of, e.g., a synthetic resin material.

The guide member 500 may prevent the FPCB 123 of the touch panel 120 passing through the opening 550 from contacting the bracket panel 300.

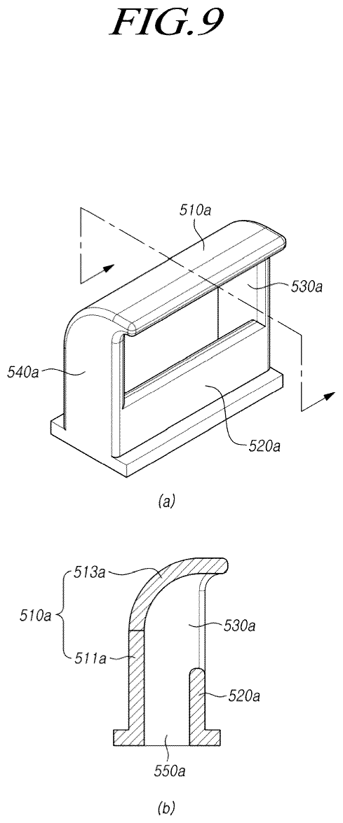

FIG. 9 is a perspective view (a) and a cross-sectional view (b) of a guide member 500 according to an embodiment.

Referring to FIG. 9, the guide member 500 may include a first rib 510a, a second rib 520a, a third rib 530a, a fourth rib 540a, and an opening 550a. The first to fourth ribs 510a, 520a, 530a, and 540a may be formed to extend in the height direction from the outer case 200 adjacent to the opening 550a. The guide member 500 may be integrally formed with the outer case 200. The guide member 500 may be formed of, e.g., a synthetic resin material.

For example, the first rib 510a may include a vertical extension 511a or a curved extension 513a. The first rib 510a may extend in the height direction and may be bent at a predetermined point. For example, the vertical extension 511a may be a portion extending vertically from the first frame 221 of the outer case 200 in the height direction. For example, the curved extension 513a may be an extension having a curved shape extending from an end of the vertical extension 511a. The predetermined point may be a boundary point between the vertical extension 511a and the curved extension 513a. The boundary point may be determined considering, e.g., a point where the FPCB 123 of the touch panel 120 is bent. The curvature of the curved extension 513a may be determined considering, e.g., the curvature of the FPCB 123 connected to the first PCB 410.

Although not shown, the curved extension 513a may be bent in a direction of approaching the fifth frame 325 of the bracket panel 300. Even if it is bent in the direction of approaching the fifth frame 325, the guide member 500 may prevent the FPCB 123 of the touch panel 120 from contacting the bracket panel 300.

As the first rib 510a is bent at a predetermined point, it is possible to effectively prevent the FPCB 123 of the touch panel 120 passing through the opening 550a from contacting the bracket panel 300.

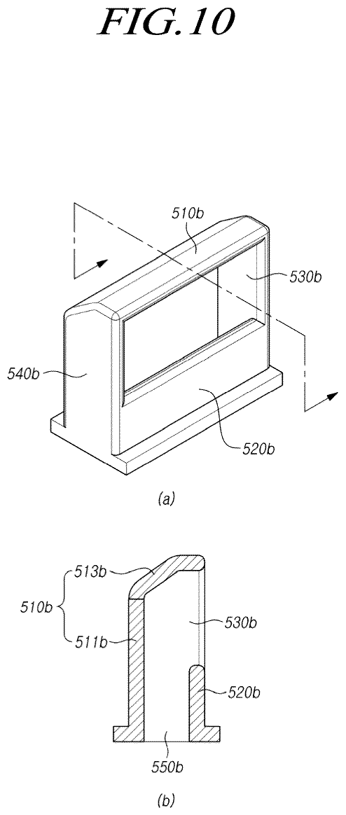

FIG. 10 is a perspective view (a) and a cross-sectional view (b) of a guide member 500 according to an embodiment.

According to FIG. 10, the guide member 500 may include a first rib 510b, a second rib 520b, a third rib 530b, a fourth rib 540b, and an opening 550b.

For example, the first rib 510b may include a vertical extension 511b or a bent extension 513b. The first rib 510a may extend in the height direction and may be bent at a predetermined angle at a predetermined point. For example, the vertical extension 511b may be a portion extending vertically from the first frame 211 of the outer case 200 in the height direction. The bent extension 513b may be, e.g., bent and extended from an end of the vertical extension 511b. The predetermined point may be a boundary point between the vertical extension 511b and the bent extension 513b. The boundary point may be determined considering, e.g., a point where the FPCB 123 of the touch panel 120 is bent. The angle formed between the vertical extension 511b and the bent extension 513b may be determined considering, e.g., the curvature of the FPCB 123 connected to the first PCB 410.

In addition to those illustrated, the bent extension 513b may be formed of, e.g., a plurality of bent ends. The plurality of bent ends may be bent at a predetermined angle, for example. The bending angle may be determined considering, e.g., the curvature of the FPCB 123 connected to the first PCB 410.

Although not shown, the bent extension 513b may be bent in the direction of approaching the fifth frame 325 of the bracket panel 300. Even if it is bent in the direction of approaching the fifth frame 325, the guide member 500 may prevent the FPCB 123 of the touch panel 120 from contacting the bracket panel 300.

As the first rib 510a is bent at a predetermined point, it is possible to effectively prevent the FPCB 123 of the touch panel 120 passing through the opening 550a from contacting the bracket panel 300.

A control box assembly 100 according to an embodiment of the disclosure may comprise a housing 150, a touch panel 120 disposed on a front surface of the housing to allow operation by a user U, a printed circuit board 410 provided inside the housing 150 and including at least one connection port 433, a flexible printed circuit board 123 extending from a predetermined point of the touch panel 120 and connected to the connection port 433, and a guide member 500 provided in the housing 150. The guide member 500 may include an opening 550 configured to allow the flexible printed circuit board 123 to be introduced into an interior of the housing to connect to the printed circuit board and at least one rib 510, 520, 530, 540 extending in a height direction from a bottom surface 221 of the housing adjacent to the opening 550.

In the control box assembly 100 according to an embodiment of the disclosure, the housing 150 may include an external case 200 having a synthetic resin material and a bracket panel 300 having a steel material inside the external case 200.

The control box assembly 100 according to an embodiment of the disclosure may further comprise a glass member 110 attached to a front surface of the touch panel 120.

In the control box assembly 100 according to an embodiment of the disclosure, the guide member 500 may include a first rib 510 disposed between the bracket panel 300 and the flexible printed circuit board 123 and extending in the height direction.

In the control box assembly 100 according to an embodiment of the disclosure, a height of the first rib 510 may be determined in consideration of a distance by which the guide member 500 is spaced apart from the bracket panel 300.

In the control box assembly 100 according to an embodiment of the disclosure, the first rib 510 may move away from the bracket panel 300 as the first rib 510 extends in the height direction.

In the control box assembly 100 according to an embodiment of the disclosure, the guide member 500 may further include a second rib 520. The second rib 520 may extend in the height direction from a position spaced apart from the first rib 510 by a width of the opening 550.

In the control box assembly 100 according to an embodiment of the disclosure, a height of the first rib 510 may be greater than a height of the second rib 520.

In the control box assembly 100 according to an embodiment of the disclosure, a position of the guide member 500 may be determined in consideration of an arrangement direction of electronic components provided inside the housing 150.

The control box assembly 100 according to an embodiment of the disclosure may further comprise a display 420 attached to a front surface of the printed circuit board 410.

An electronic device 1 according to an embodiment of the disclosure may comprise a control box assembly 100. A control box assembly 100 may comprise a housing 150 including an external case 200 having a synthetic resin material and a bracket panel 300 having a steel material inside the external case 200, a touch panel 120 disposed on a front surface of the housing 150 to easily allow operation by a user U, a printed circuit board 410 attached to the bracket panel 300 and including at least one connection port 433, 435, a flexible printed circuit board 123 including one end electrically coupled to the touch panel 120 and another end including a second connection port configured to be fitted into and coupled to a first connection port 433 of the printed circuit board 410, an opening 550 formed to pass through the external case 200 and the bracket panel 300 to connect an exterior and an interior of the housing 150, and a rib 510, 520, 530, 540 configured to have a predetermined height from a bottom surface of the outer case 200 to serve as a barrier between the opening 550 and one side surface of the bracket panel 300. The flexible printed circuit board 123, which is introduced from the exterior into the interior of the housing 150 through the opening 550, may be maintained at a distance so as to be spaced apart from one side surface 325 of the bracket panel 300 due to the rib 510, 520, 530, 540.

The control box assembly 100 according to an embodiment of the disclosure may further comprise a glass member 110 attached to a front surface of the touch panel 120.

In the control box assembly 100 according to an embodiment of the disclosure, the rib 510, 520, 530, 540 may include a first rib 510 disposed between the bracket panel 300 and the flexible printed circuit board 123 and extending in a height direction.

In the control box assembly 100 according to an embodiment of the disclosure, the rib 510, 520, 530, 540 may further include a second rib 520. The second rib 520 may extend in the height direction from a position spaced apart from the first rib 510 by a width of the opening 550.

In the control box assembly 100 according to an embodiment of the disclosure, a height of the rib 510, 520, 530, 540 may be determined in consideration of a distance by which the rib 510, 520, 530, 540 is spaced apart from the bracket panel 300.

In the control box assembly 100 according to an embodiment of the disclosure, a position of the rib 510, 520, 530, 540 may be determined in consideration of an arrangement direction of electronic components provided inside the housing 150.

The terms as used herein are provided merely to describe some embodiments thereof, but are not intended to limit the technical features of the disclosure. As used herein, the singular forms “a,” “an,” and “the” are intended to include the plural forms as well, unless the context clearly indicates otherwise.

As used herein, each of such phrases as “A or B,” “at least one of A and B,” “at least one of A or B,” “A, B, or C,” “at least one of A, B, and C,” and “at least one of A, B, or C,” may include all possible combinations of the items enumerated together in a corresponding one of the phrases. As used herein, the term ‘and/or’ should be understood as encompassing any and all possible combinations by one or more of the enumerated items. As used herein, such terms as “1st” and “2nd,” or “first” and “second” may be used to simply distinguish a corresponding component from another, and does not limit the components in other aspect (e.g., importance or order).

When a (e.g., first) component is mentioned as “coupled to,” “connected to,” “supported by,” or “contacting” another (e.g., second) component with or without the terms “functionally” or “communicatively,” the component may be directly or indirectly coupled to, connected to, supported by, or contact the other component.

It will be further understood that the terms “comprise” and/or “have,” as used herein, specify the presence of stated features, integers, steps, operations, elements, and/or components, but do not preclude the presence or addition of one or more other features, integers, steps, operations, elements, components, and/or groups thereof. Throughout the specification, when one component is positioned “on” another component, the first component may be positioned directly on the second component, or other component(s) may be positioned between the first and second component.

As used herein, the terms “configured to” may be interchangeably used with the terms “suitable for,” “having the capacity to,” “designed to,” “adapted to,” “made to,” or “capable of” depending on circumstances. The term “configured to” does not essentially mean “specifically designed in hardware to.” Rather, the term “configured to” may mean that a device can perform an operation together with another device or parts. For example, a ‘device configured (or set) to perform A, B, and C’ may be a dedicated device to perform the corresponding operation or may mean a general-purpose device capable of various operations including the corresponding operation.

The terms “upper side”, “lower side”, and “front and rear directions” used in the disclosure are defined with respect to the drawings, and the shape and position of each component are not limited by these terms.

In the disclosure, the above-described description has been made mainly of specific embodiments, but the disclosure is not limited to such specific embodiments, but should rather be appreciated as covering all various modifications, equivalents, and/or substitutes of various embodiments. With regard to the description of the drawings, similar reference numerals may be used to refer to similar or related elements.

What is claimed is:

1. A control box assembly, comprising:
a housing;
a touch panel to be disposed on a front surface of the housing so that while the touch panel is disposed on the front surface of the housing, the touch panel to allow operation to be performed by a user;
a printed circuit board, arrangeable inside the housing, and including at least one connection port;
a flexible printed circuit board extending from a predetermined point of the touch panel and be connected to the least one connection port; and
a guide member arrangeable in the housing, wherein the guide member includes:
an opening configured to allow the flexible printed circuit board to be introduced into an interior of the housing to connect to the printed circuit board while the printed circuit board is arranged in the housing; and
at least one rib extending along a height direction of a bottom surface of the housing adjacent to the opening.

2. The control box assembly of claim 1, wherein the housing includes an external case having a synthetic resin material and a bracket panel having a steel material inside the external case.

3. The control box assembly of claim 1, further comprising a glass member attached to a front surface of the touch panel.

4. The control box assembly of claim 1, wherein the at least one rib of the guide member is a first rib disposed between a bracket panel and the flexible printed circuit board and extending along a height direction.

5. The control box assembly of claim 4, wherein a height of the first rib based on a distance by which the guide member is spaced apart from the bracket panel.

6. The control box assembly of claim 4, wherein the first rib is moveable away from the bracket panel as the first rib extends in the height direction.

7. The control box assembly of claim 4, wherein among the at least one rib of the guide member is a second rib, and
wherein the second rib extends along the height direction from a position spaced apart from the first rib by a width of the opening.

8. The control box assembly of claim 7, wherein a height of the first rib is greater than a height of the second rib.

9. The control box assembly of claim 1, wherein a position of the guide member is based on an arrangement direction of electronic components provided inside the housing.

10. A control box assembly included in an electronic device, the control box assembly comprising:
a housing including an external case having a synthetic resin material and a bracket panel having a steel material inside the external case;
a touch panel to be disposed on a front surface of the housing to allow operation to be performed by a user;
a printed circuit board, attachable to the bracket panel, and including at least one connection port;
a flexible printed circuit board including one end electrically coupleable to the touch panel and another end including a second connection port configured to be fitted into and be coupleable to a first connection port of the printed circuit board;
an opening formed to allow passage through the external case and the bracket panel to connect an exterior and an interior of the housing; and
a rib configured to have a predetermined height from a bottom surface of an outer case to serve as a barrier between the opening and one side surface of the bracket panel,
wherein the flexible printed circuit board, which is introduced from the exterior to the interior of the housing through the opening, is maintained at a distance so as to be spaced apart from one side surface of the bracket panel due to the rib.

11. The control box assembly of claim 10, further comprising a glass member attached to a front surface of the touch panel.

12. The control box assembly of claim 10, wherein the rib is a first rib disposed between the bracket panel and the flexible printed circuit board and extending along a height direction of the bottom surface of the outer case.

13. The control box assembly of claim 12, wherein the control box assembly further includes a second rib, and
wherein the second rib extends along the height direction from a position spaced apart from the first rib by a width of the opening.

14. The control box assembly of claim 10, wherein a height of the rib is based on a distance by which the rib is spaced apart from the bracket panel.

15. The control box assembly of claim 10, wherein a position of the rib is based on an arrangement direction of electronic components provided inside the housing.
